(19) United States
(12) Patent Application Publication
(10) Pub. No.: US 2007/0065597 A1
(43) Pub. Date: Mar. 22, 2007

(54) Plasma CVD film formation apparatus provided with mask

(75) Inventors: Shintaro Kaido, Tokyo (JP); Masashi Yamaguchi, Tokyo (JP); Yoshinori Morisada, Tokyo (JP); Nobuo Matsuki, Tokyo (JP); Kyu Tae Na, Hwasung-City (KR); Eun Kyung Baek, Hwasung-City (KR)

Correspondence Address: KNOBBE MARTENS OLSON & BEAR LLP, 2040 MAIN STREET, FOURTEENTH FLOOR, IRVINE, CA, 92614, US

(73) Assignees: ASM JAPAN K.K., Tokyo (JP); SAMSUNG ELECTRONICS CO., LTD., Hwasung-City (KR)

(21) Appl. No.: 11/227,525

(22) Filed: Sep. 15, 2005

(51) Int. Cl. C23C 16/00; H05H 1/24

(52) U.S. Cl. 427/569; 118/723 E; 118/720

(57) ABSTRACT

A plasma CVD apparatus for forming a thin film on a wafer having diameter Dw and thickness Tw, includes: a vacuum chamber; a shower plate; a top plate; a top mask portion for covering a top surface peripheral portion of the wafer; and a side mask portion for covering a side surface portion of the wafer. The side mask portion has an inner diameter of Dw+α, and the top mask portion is disposed at a clearance of Tw+β between a bottom surface of the top mask portion and a wafer-supporting surface of the top plate, wherein α is more than zero, and β is more than zero.

### BACKGROUND OF THE INVENTION

1. Field of the Invention

The present invention generally relates to a semiconductor manufacturing apparatus and more particularly to a plasma CVD film formation apparatus which is characterized by a structure in the vicinity of a top plate.

2. Description of the Related Art

FIG. 1 is a schematic view of a conventional plasma processing apparatus. The plasma processing apparatus 1 comprises a reaction chamber 6, a gas inlet port 5, a circular upper electrode 9, and a lower electrode comprised of a top plate 3 and a heater 2. From a gas line (not shown), a gas is introduced through the gas inlet port 5. The circular upper electrode 9 is disposed directly below the gas inlet port 5. The upper electrode 9 has a hollow structure and a number of fine pores provided at its bottom from which a gas is jetted out toward the wafer 4. In this case, the upper electrode 9 has a structure in which a shower plate 11 having plural gas inlet holes is replaceable so as to facilitate maintenance work and reduce component costs.

Additionally, at the bottom of the reaction chamber 6, an exhaust port 10 is provided. This exhaust port is connected to an external vacuum pump (not shown); consequently, the interior of the reaction chamber 6 is exhausted. The top plate 3 is disposed parallel to and facing the upper electrode 9. The top plate supports the wafer 4 thereon, heats the wafer 4 continuously by the heater 2, and maintains the wafer 4 at a given temperature (−50-650° C.). The gas inlet port 5 and the upper electrode 19 are electrically insulated from the reaction chamber 6 and connected to an external first radio-frequency power source 7. In this drawing, a second radio-frequency power source 8 is also connected. Numeral 12 indicates grounding. Thus, the upper electrode 9 and the lower electrode function as radio-frequency electrodes and generate a plasma reaction field in the vicinity of the wafer 4. The type and characteristics of a resulting film formed on a surface of the wafer 4 vary depending on the type and flow rate of source gas, the temperature, the RF frequency, plasma space distribution, and electric potential distribution.

However, in the conventional technique, because a film is formed on a top surface peripheral portion and a side portion of the wafer and particles are generated depending on a process, it is necessary to prevent film formation on these portions. U.S. Pat. No. 4,932,358, Japanese Patent Laid-open No. 4-268724, and U.S. Pat. No. 5,304,248 disclose a method in which a periphery of a wafer is covered by a shield or seal ring only in the context of thermal CVD, and the ring is in contact with at least a part of the wafer.

However, if this method is used with plasma CVD by installing a ring at a wafer edge portion, abnormal film growth occurs in the vicinity of the mask, thereby causing poor uniformity of film thickness, for example.

### SUMMARY OF THE INVENTION

Consequently, in an aspect, an object of the present invention is to provide a plasma CVD film formation apparatus which prevents film formation on a top surface peripheral portion and a side portion of a wafer, and yet forms a film having a uniform film thickness and uniform film characteristics.

Additionally, another object of the present invention is to provide a plasma CVD film formation apparatus at inexpensive manufacturing costs and with a simple configuration.

Yet another object of the present invention is to provide a method of plasma CVD film formation at a high uniformity of film thickness without film deposition at the peripheral portion of a wafer.

The present invention can accomplish one or more of the above-mentioned objects in various embodiments. However, the present invention is not limited to the above objects, and in embodiments, the present invention exhibits effects other than the objects.

In an aspect, the present invention provides a plasma CVD apparatus for forming a thin film on a wafer having diameter Dw and thickness Tw, comprising: (i) a vacuum chamber; (ii) a shower plate installed inside the vacuum chamber which serves as one of two electrodes; (iii) a top plate for placing the wafer thereon installed substantially parallel to and facing the shower plate, said top plate serving as the other electrode and being movable between a lower position and an upper position; (iv) a top mask portion for covering a top surface peripheral portion of the wafer, said top mask portion being disposed at a clearance of Tw+β (wherein β=more than zero, preferably β=0.05-0.75 mm, including 0.1 mm, 0.2 mm, 0.4 mm, 0.6 mm, 0.7 mm, and values between any two numbers of the foregoing) between a bottom surface of the top mask portion and a wafer-supporting surface of the top plate; and (v) a side mask portion for covering a side surface portion of the wafer when the top plate is at the upper position, said side mask portion having an inner diameter of Dw+α (wherein α=more than zero, e.g., 0.03-4 mm, preferably α=0.05-2 mm, including 0.1 mm, 0.5 mm, 1.0 mm, 1.5 mm, and values between any two numbers of the foregoing). Due to the top and side mask portion, unwanted film formation at an edge portion of the wafer can effectively be prevented without suffering film thickness uniformity (for example, 10% or less can be maintained). The non-uniformity is measured by comparing the thickness of the film at a center (Tc) and the thickness of the film in the vicinity of the edge (Te), i.e., Te/Tc. The wafer can be an oriental flat wafer which has a flat portion along its outer periphery. In that case, Dw is defined as a greatest outer diameter of the wafer.

The above embodiment includes, but is not limited to, the following embodiments:

The top mask portion may have a bulk resistivity of about 10⁻⁵ Ω·cm to about 10³ Ω·cm. When a material such as silicon having the above bulk resistivity is used as the top mask portion, unwanted film formation at the edge portion of the wafer can be prevented without lowering film thickness uniformity. However, in an embodiment, silicon may be apt to deterioration by etching during a plasma cleaning process, causing damage to the mask. When a material such as ceramics (e.g., Al₂O₃) is used as the bevel mask, the problem of deterioration by etching can be solved. For example, the top mask portion may have a bulk resistivity of about 10⁶ Ω·cm or higher. However, film thickness non-uniformity may increase by plasma CVD to about 15%, for example. Thus, in an embodiment, the shower plate may be comprised of a gas discharge portion and a base portion, wherein the gas discharge portion has diameter Ds which satisfies Dw−d<Ds<Dw+3d (d is a distance between the shower plate and the top plate), including Dw−0.5d<Ds<Dw+2.5d, Dw<Ds<Dw+2d, Dw+0.5d<Ds<Dw+1.5d, and ranges defined by any combination of the foregoing. In an embodiment, the inequality Dw<Ds<Dw+2d may be satisfied. In the above, the area of enhanced plasma can be controlled, thereby increasing the film uniformity. In an embodiment, d may be in the range of about 3 mm to about 50 mm (in an embodiment, 7-25 mm or 10-20 mm).

In an embodiment, the top mask portion and the side mask portion are integrated and constitute a bevel mask. In another embodiment, the side mask portion is a part of the top plate. In still another embodiment, the side mask portion is a part of a dielectric ring structure installed at the periphery of the top plate. In an embodiment, the side mask portion is entirely or partially constituted by the ring structure or the bevel mask. For convenience, an integrated portion including the top mask portion may be referred to as a “bevel mask” or “mask”. Thus, the bevel mask includes at least the top mask portion, and may further include the entire or a part of the side mask portion.

When the side mask portion is constituted by a part of the top plate, the top plate itself may be dielectric (e.g., an AlN top plate). A heater and an electrode can be installed in another block on which the dielectric top plate is mounted. Alternatively, a heater and/or electrode can be embedded in the dielectric top plate.

In an embodiment, the gas discharge portion may be planate. In another embodiment, the gas discharge portion may be constructed by plural gas inlet bores and plasma enhance spikes protruding downward from a surface on which the plural gas inlet bores are formed, wherein Ds is an outer diameter of an area defined by outermost spikes of the plasma enhance spikes. In an embodiment, an area defined by outermost bores of the plural gas inlet bores may have diameter Dh which satisfies Ds−2d<Dh (in an embodiment, Ds−d<Dh). The bores may have a diameter of about 0.2 mm to about 2 mm (in an embodiment about 0.4 mm to about 1.0 mm), and the spikes may have a length of about 1 mm to about 10 mm (in an embodiment, about 2 mm to about 6 mm). The shower plate having plasma enhance spikes, which is disclosed in U.S. patent application Ser. No. 11/061,986, filed Feb. 18, 2005 owned by ASM Japan K.K. which is one of the assignees of the present application (the disclosure of which is incorporated herein by reference in its entirety), can be used in an embodiment of the present invention.

In an embodiment, the top plate may be conductive and have an outer annular recess around its periphery and a dielectric ring structure placed on the annular recess for supporting the wafer thereon. The dielectric ring structure may have an inner annular recess. A plane formed by a top peripheral surface of the dielectric ring structure may be higher than a plane formed by a top surface of the conductive top plate. The dielectric ring structure may have an inner diameter of 0.8Dw to 1.2Dw (in an embodiment, 0.9 to 1.1). In the above, an area of enhanced plasma can be controlled, thereby increasing the film uniformity.

In an embodiment, the top mask portion may have a thickness of about 2 mm or less (including 0.3 mm, 0.5 mm, 1.0 mm, 1.5 mm, and values between any two numbers of the foregoing) at an inner periphery and have an inwardly tapered portion (preferably annular). In an embodiment, the top mask portion may cover a top surface of the wafer in a range of about 0.3 mm to about 3 mm (including 0.5 mm, 1.0 mm, 1.5 mm, 2.0 mm, 2.5 mm, and values between any two numbers of the foregoing) from the outermost periphery of the wafer.

In the above, when the numeral ranges are defined by two numerals, the numerals can be inclusive or exclusive in the ranges.

In an embodiment, the bevel mask may be composed of one or more materials selected from the group consisting of aluminum, aluminum oxide, aluminum nitride, silicon, silicon oxide, silicon carbide, silicon nitride, boron nitride, and metal impregnated ceramic.

In an embodiment, the top plate may have outer diameter Dss which satisfies 1.04Dw<Dss<1.5Dw (preferably 1.1Dw<Dss<1.3Dw). In an embodiment, the side mask portion may rest on a top peripheral surface of the top plate (outside the wafer) when at the upper position (the top peripheral surface need not be the highest surface and can be the lowest surface of the top plate). In another embodiment, the side mask portion may rest on a top peripheral surface of the dielectric ring structure (outside the wafer).

In all of the aforesaid embodiments, any element used in an embodiment can interchangeably be used in another embodiment unless such a replacement is not feasible or causes adverse effect. Further, the present invention can equally be applied to apparatuses and methods.

In an aspect, the present invention provides a method for forming by plasma CVD a thin film on a wafer (having a non-uniformity of film thickness of 10% or less, for example), comprising: (i) placing the wafer on a top plate installed substantially parallel to and facing a shower plate; (ii) placing a top mask portion over the wafer, wherein the top mask portion covers a top surface peripheral portion of the wafer at a clearance therebetween of more than zero (preferably 0.05-0.75 mm), wherein a side mask portion is disposed at a periphery of the top plate and covers a side surface portion of the wafer at a clearance therebetween of more than zero (preferably 0.05-2 mm); and (iii) applying radio-frequency power between the top plate and the shower plate to form a thin film on the wafer by plasma CVD.

For example, the above embodiment includes, but is not limited to, the following embodiments:

The method may further comprise providing the shower plate comprised of a gas discharge portion and a base portion, said gas discharge portion having diameter Ds which satisfies Dw−d<Ds<Dw+3d, wherein Dw is a diameter of the wafer and d is a distance between the shower plate and the top plate. The method may further comprise providing the top plate being conductive and having an outer annular recess around its periphery and a dielectric ring structure placed on the annular recess for supporting the wafer thereon. The method may further comprise providing the top mask portion having a thickness of about 2 mm or less at an inner periphery and having an inwardly tapered portion. The method may further comprise providing the bevel mask composed of one or more materials selected from the group consisting of aluminum, aluminum oxide, aluminum nitride, silicon, silicon oxide, silicon carbide, silicon nitride, boron nitride, and metal impregnated ceramic. The method may further comprise providing the top plate having outer diameter Dss which satisfies 1.04Dw<Dss<1.5Dw, wherein Dw is a diameter of the wafer.

In the above methods, any element used in any embodiment of the apparatus can be used singly or in any combination.

For purposes of summarizing the invention and the advantages achieved over the related art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes.

FIG. 1 is a schematic diagram showing a conventional plasma CVD apparatus.

FIG. 2 is a schematic diagram showing an embodiment of the present invention.

FIG. 3 is a graph showing distributions of thickness of films according to embodiments of the present invention, wherein a Si bevel mask and a ceramic bevel mask were used, respectively.

FIG. 4 is a graph showing distributions of thickness of films according to embodiments of the present invention, wherein a flat ring and a trench-type ring were used, respectively.

FIG. 5 is a graph showing distributions of thickness of films according to embodiments of the present invention, wherein clearance α was set at 0.075 mm, 0.325 mm, and 0.575 mm, respectively.

FIG. 6 is a graph showing distributions of thickness of films according to embodiments of the present invention, wherein shower plates (with plasma enhance spikes) having diameters of 250 mm, 220 mm, and 200 mm, respectively, were used with a trench-type top plate.

FIG. 7 is a schematic cross sectional diagram (partial) showing an embodiment of the present invention.

FIG. 8 is a schematic cross sectional diagram (partial) showing an embodiment of the present invention.

FIG. 9 is a graph showing distributions of thickness of films according to embodiments of the present invention, wherein no mask (STD) and a ceramic bevel mask were used, respectively.

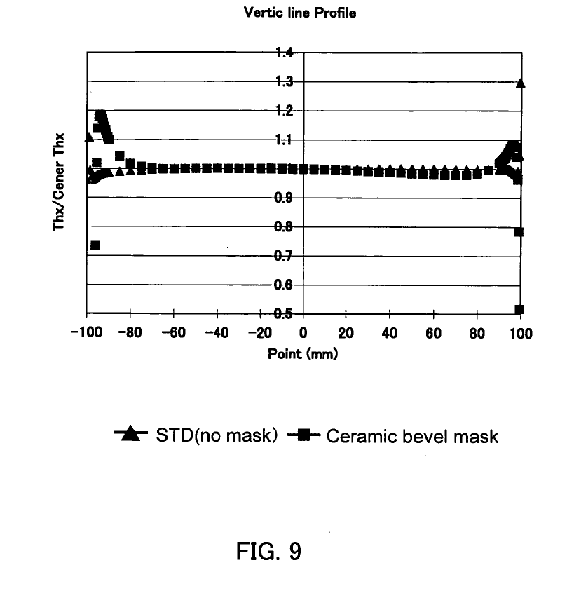

FIG. 10 is a graph showing distributions of thickness of films according to embodiments of the present invention, wherein clearance Cs was set at Dw, Dw+d, Dw+2d, and Dw+3d, respectively.

FIG. 11 is a schematic cross sectional diagram (partial) showing an embodiment of the present invention.

FIG. 12 is a graph showing distributions of thickness of films according to embodiments of the present invention, wherein shower plates (with plasma enhance spikes) having diameters of 250 mm, 220 mm, and 200 mm, respectively, were used with a flat-type top plate.

FIG. 13 is a chart showing schematic cross sectional diagrams (partial) of various embodiments of the present invention.

### DETAILED DESCRIPTION OF THE PREFERRED EMBODIMENT

The present invention will be explained in detail with reference to preferred embodiments. However, the preferred embodiments are not intended to limit the present invention.

The wafer which can be processed in the present invention includes, but is not limited to, a wafer having a diameter of 200 mm with a thickness of 0.725±0.025 mm and a wafer having a diameter of 300 mm with a thickness of 0.775±0.025 mm. By selecting a bevel mask having dimensions suitable for the wafer-to-be-processed, no limitation may be imposed on the wafer size. In addition, if it is necessary, the top plate and the shower plate can be suitably selected depending on the wafer size. In the case of an oriental flat wafer, the mask and the shower plate may be configured to correspond to the outer shape of the oriental flat wafer. Further, in the case of a notched wafer, the mask may be configured to cover the notched portion by locally extending inward a portion corresponding to the notched portion. In the above, the “diameter” normally means the greatest diameter.

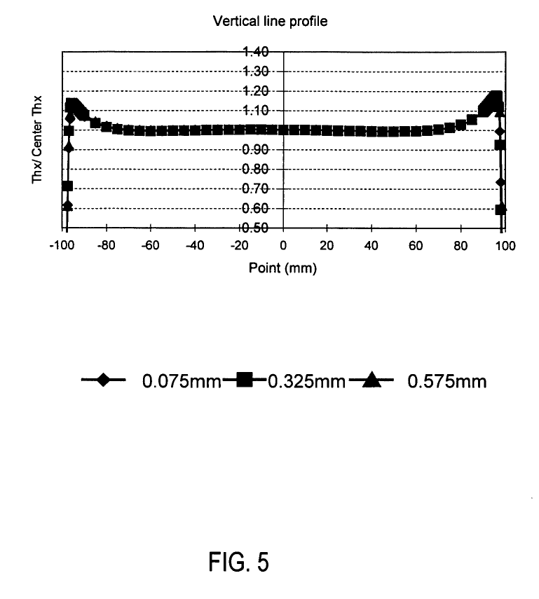

In the present invention, the bevel mask is not in contact with any part of the wafer. If the mask is in contact with the wafer, particles tend to be generated. If the wafer and the mask are apart, irregular plasma discharge may occur. If the clearance between the wafer and the mask becomes greater, film formation on a top surface peripheral portion of the wafer cannot be prevented. In view of the above, in an embodiment, clearance β (a clearance between a bottom surface of the top mask portion and a top surface of the wafer) may be more than zero (preferably 0.05-0.75 mm) (see Example 3, FIG. 5). In an embodiment, clearance α (a clearance between an inner surface of the side mask portion and a side surface of the wafer) may be more than zero (preferably 0.05-2 mm).

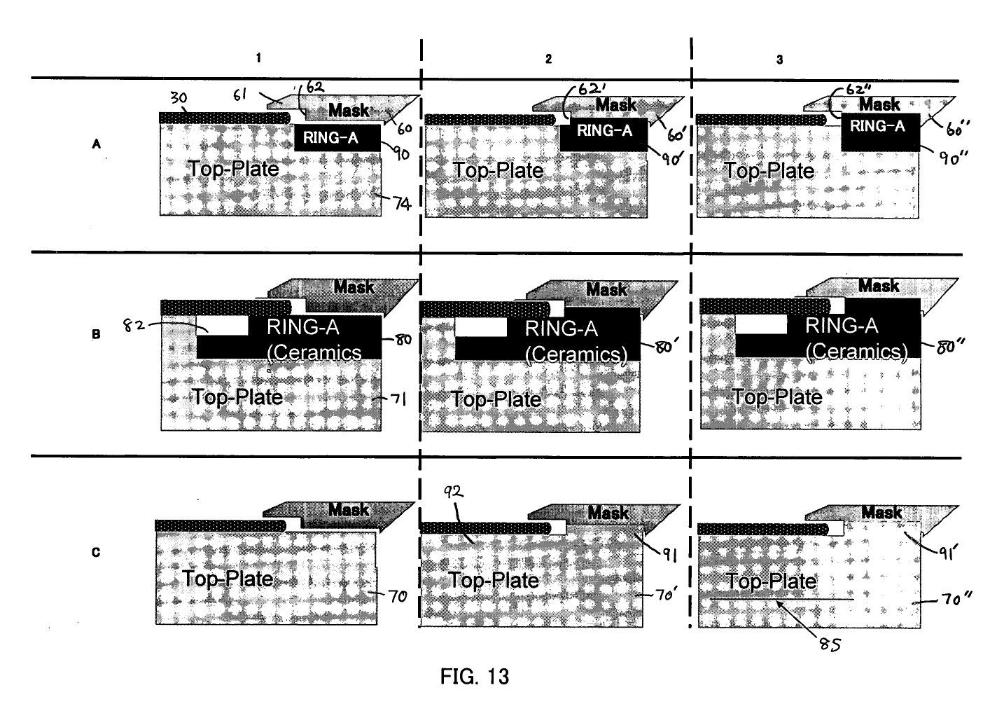

The side mask portion 62 may be constituted by a bevel mask 60 as shown in A1, B1, and C1 in FIG. 13 (this figure is oversimplified for illustrative purposes). In this embodiment, the side mask portion 62 and the top mask portion 61 are integrally formed or molded, constituting the bevel mask 60. In another embodiment, a side mask portion 62′ may be constituted by both of a bevel mask 60′ and a ring structure 90′/80′ or a peripheral convex portion 91 of the top plate 70′ as shown in A2, B2, and C2 in FIG. 13. In still another embodiment, a side mask portion 62″ may be constituted by a ring structure 90″/80″ or a peripheral convex portion 91′ of the top plate 70″ as shown in A3, B3, and C3 in FIG. 13. In all of the cases, the clearance α can properly be determined as a distance between a side surface portion of the wafer and a surface of the side mask portion 62, 62′, and 62″.

The bevel masks 60, 60′, and 60″ may rest on the ring structures 90, 90′, and 90″ without a trench as shown in A1, A2, and A3 in FIG. 13, respectively. In another embodiment, the bevel masks 60, 60′, and 60″ may rest on the ring structures 80, 80′, and 80″ with a trench 82 as shown in B1, B2, and B3 in FIG. 13, respectively. In still another embodiment, the bevel masks 60, 60′, and 60″ may rest on the top plates 70, 70′, and 70″ as shown in C1, C2, and C3 in FIG. 13, respectively. In yet another embodiment, the bevel mask may not rest on a surface of the ring structure or the top plate but may be supported by another structure such as lifting pins. In C2 and C3 in FIG. 13, the top plate 70′ or 70″ includes the peripheral convex portion 91 or 91′ having a top surface which is higher than that of a wafer-supporting portion 92, and thus, in order to adjust plasma excitation at the peripheral area, the top plate is preferably made of a dielectric material such as AlN, whereas the top plate in A1-A3 and B1-B3 in FIG. 13 may be conductive (the ring structure may be dielectric). Further, in C3 in FIG. 13, a heater 85 (and an electrode) can be embedded in the top plate 70″/In C2 in FIG. 13, a heater (and an electrode) may be installed in another block on which the dielectric top plate is mounted.

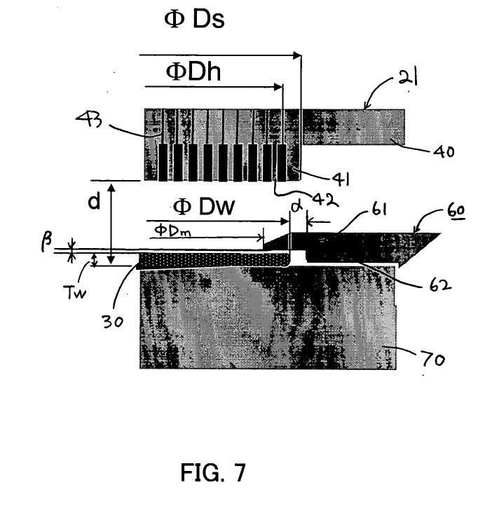

A1, B1, and C1 in FIG. 13 will be explained further in FIGS. 11, 8, and 7, respectively.

The mask may rest on the top plate or another member such as a mask supporting member vertically installed around the top plate or mask lifting pins inserted in through holes provided in the vicinity of the periphery of the top plate outside a wafer placing area. The mask may also be suspended from an upper portion of a reactor or supported on a support extended from a side wall of the reactor. The mask can structurally be connected to a supporting member or may be unconnected to any member but rest on a member.

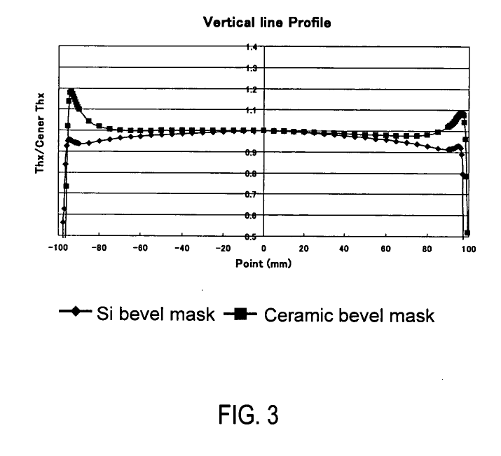

The mask may be composed of one or more materials selected from the group consisting of aluminum, aluminum oxide, aluminum nitride, silicon, silicon oxide, silicon carbide, silicon nitride, boron nitride, and metal impregnated ceramic. When a material having a bulk resistivity similar to that of the wafer, such as silicon having a bulk resistivity of about 10⁻⁵ Ω·cm to about 10³ Ω·cm, is used as the bevel mask, unwanted film formation at the edge portion of the wafer can be prevented without lowering film thickness uniformity (see Example 1, FIG. 3).

However, silicon may be apt to deterioration by etching during a plasma cleaning process, causing damage to the mask. When a material such as ceramics (e.g., Al₂O₃) is used as the bevel mask, the problem of deterioration by etching can be solved. For example, the bevel mask may have a bulk resistivity of about 10⁶ Ω·cm or higher, and in another embodiment, the bulk resistivity may be 10⁻⁵ Ω·cm or 10⁶ Ω·cm. However, film thickness non-uniformity may increase by plasma CVD to about 15%, for example (see Example 1, FIG. 3).

An upper surface of the bevel mask faces the shower plate (an upper electrode) and is exposed to a plasma. In the case the mask is dielectric, in an embodiment, in a portion covered by the dielectric mask, a Si wafer of approximately 0.8 mm thickness is placed on the top plate (a lower electrode) and further is covered by the dielectric masks of approximately 0.5-1 mm thickness, for example, on top of it. Additionally, the mask has a thickness of approximately 2-5 mm, for example, at an outer peripheral portion outside the wafer, which is required in order to provide sufficient strength from a processing viewpoint. Consequently, a Si wafer surface inside the mask's inner edge and a ceramic portion outside the mask's inner edge become electrically non-uniform against the facing electrode and a plasma. For this reason, abnormal growth of a film thickness occurs on the Si wafer in the vicinity of approximately 0.5-1.0 mm, for example, from the mask's inner edge due to localized plasma concentration.

In an embodiment, as to a portion outside the mask's inner edge in which plasma concentration occurs, by increasing an effective distance between the upper electrode and the lower electrode, plasma concentration outside the vicinity of the mask's inner edge can be alleviated, thereby actualizing film thickness uniformity. The effective distance is an electrical distance between the upper and lower electrodes considered a capacitor, and need not be a actual or physical distance.

If a shower plate in which protrusions (plasma enhance spikes) are disposed is used, by disposing the protrusions only on an inner side corresponding to an inner area surrounded by the mask's inner edge so as to moderate plasma intensity on a portion outside the mask's inner edge, plasma concentration in the vicinity of the mask's inner edge can be alleviated.

Additionally, if a planate shower plate without protrusions is used, by widening an effective distance between the upper and lower electrodes in an area outside the mask's inner edge, plasma concentration in the vicinity of the mask's inner edge can be alleviated.

Further, the effective distance between the upper and lower electrodes can be adjusted by placing a dielectric ring structure on a periphery of the top plate (lower electrode).

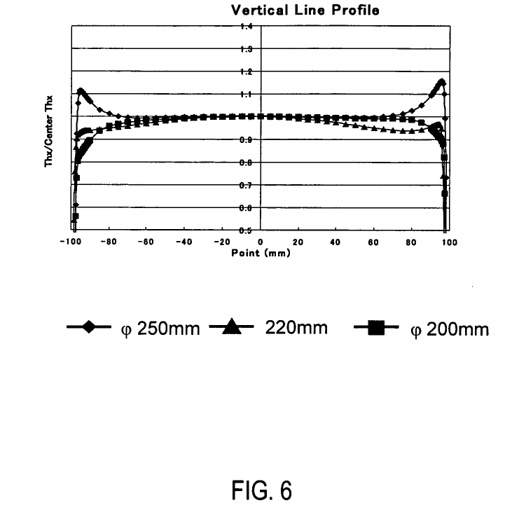

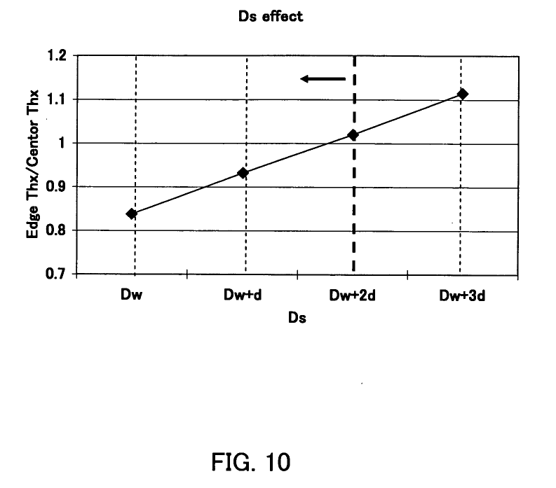

In an embodiment, the shower plate may be comprised of a gas discharge portion and a base portion, wherein the gas discharge portion has diameter Ds which satisfies Dw−d<Ds<Dw+3d (Dw is a diameter of the wafer, and d is a distance between the shower plate and the top plate). In other embodiments, Dw−0.5d<Ds<Dw+2.5d, Dw<Ds<Dw+2d; Dw+0.5d<Ds<Dw+1.5d; or any other combinations of minimum and maximum numbers can be employed. In the above, the area of enhanced plasma can be controlled, thereby increasing the film uniformity (see Example 5, FIG. 10, also Examples 4 and 6, FIGS. 6 and 13). In the above, “a bulk resistivity” means a resistivity of a material constituting the mask, not a coating which may be formed thereon.

In an embodiment, the top portion of the bevel mask (the top mask portion) may have a thickness of about 2 mm or less (e.g., 0.5-1 mm) at an inner periphery and have an inwardly tapered portion (preferably annular). In an embodiment, the tapered angle may be 10°-45° or 20°-30° with respect to a top surface of the wafer or the top plate. In an embodiment, the bevel mask may cover a top surface of the wafer in a range of about 0.3 mm to about 3 mm from the outermost periphery of the wafer. This range may also apply to a length of the tapered portion. These configurations affect plasma intensity in the vicinity of the wafer edge, contributing to high uniformity of film thickness.

Any suitable shower plate can be used in an embodiment. However, in an embodiment, on a surface of the shower plate, plural gas inlet holes, and protrusions protruding from the surface are formed. FIG. 7 shows a partial cross-sectional view of an embodiment. This figure is oversimplified for illustrative purposes, for example, a mask 60 is in fact in contact with a top peripheral surface of a top plate 70 in this embodiment. Further, a heater is not shown in this figure. The heater can be embedded in the top plate as shown in C3 in FIG. 13 or can be separated from the top plate (e.g., a top plate is placed on a heater). A shower plate 21 is comprised of a base portion 40 and a gas discharge portion 41. Protrusions (plasma enhance spikes) 42 are disposed uniformly around fine bores 43 for introducing a gas and have a shape of a polyangular column or a polyangular pyramid such as a hexagonal column and a quadangular pyramid, for example. By conforming a diameter (Ds) of an area in which the protrusions 42 are disposed nearly to an internal diameter (Dm) of a bevel mask 60, abnormal film thickness growth in the vicinity of an inner edge portion of the mask is prevented, thereby obtaining a film having a uniform thickness. As described, Ds satisfies the inequality Dw−d<Ds<Dw+3d, and the equation (Dw−Dm)=2γ (e.g., γ=0.5-2.5 mm) is also satisfied. Thus, the inequality Dm+2γ−d<Ds<Dm+2γ+3d is satisfied. Here, γ may be about 1% of Dm and about 10% of d, and thus, in an embodiment, the inequality Dm−d<Ds<Dm+3d may substantially be satisfied.

In an embodiment, the size of the bores 43 may be 0.2 mm to about 2 mm, and the height of the protrusions 42 may be about 2 mm to about 10 mm. The shower plate may be made of aluminum with an anodized surface, for example. Detailed information regarding the shower plate like this embodiment is described in U.S. patent application Ser. No. 11/061,986, filed Feb. 18, 2005 owned by ASM Japan K.K. which is one of the assignees of the present application, the disclosure of which is incorporated herein by reference in its entirety.

When an interval between upper and lower electrodes (in this embodiment, the shower plate 11 and the top plate 70) is referred to as d and a diameter of the wafer 30 is referred to as Dw, diameter Ds of an area having the protrusions 41 of the shower plate 11 may satisfy Dw−d<Ds<Dw+3d in an embodiment. When Ds is in this range, the film uniformity can be improved. Further, diameter Dh of an area having the plural gas bores 43 may satisfy Ds−2d<Dh in an embodiment. In another embodiment, Dw may be nearly the same as Dh. In the above, d may be about 3 mm to about 50 mm (preferably 10-25 mm).

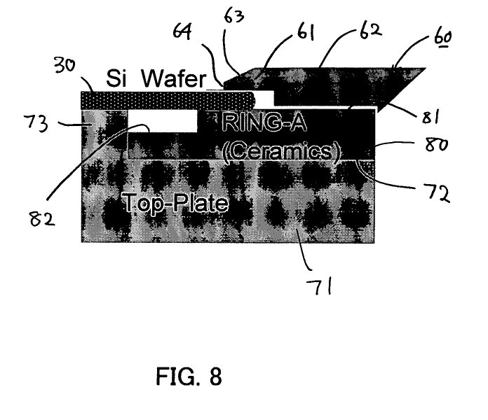

In order to prevent film formation on a top surface peripheral portion and a side surface portion of the wafer, providing a clearance between the mask and a top surface of the wafer is essential; in order to avoid direct contact and abnormal discharge, the clearance is required to fall within a specific range. The distance between a bottom surface of a top portion 61 (see FIG. 8) of the bevel mask 60 (a top mask portion) and a wafer-supporting surface of the top plate 70 is substantially equal to thickness Tw of the wafer 30 plus gap β (β is a distance between the top portion 61 of the mask and a top surface of the wafer 30). β is more than zero (preferably 0.05-0.75 mm). Inner diameter Db is substantially equal to Dw plus 2×α (α is a distance between a side surface portion of the wafer 30 and a side portion 62 (see FIG. 8) of the mask 60, i.e., a side mask portion). α is more than zero (preferably 0.05-2 mm).

Further, in this embodiment, an inner periphery 64 of the top portion 61 of the mask 60 may have a thickness of about 2 mm or less (e.g., 0.5-1 mm), and the top portion 61 may have an inwardly tapered portion 63. The tapered portion 63 may have a length which covers the periphery of the wafer 30. Due to the tapered portion 63, the effective electrode distance can be gradually greater toward the periphery of the wafer, thereby reducing decreasing plasma concentration at the periphery of the wafer.

In an embodiment, if an oriental flat wafer is used instead of a circular Si wafer, the bevel mask having a shape where an inner edge of the bevel mask runs along an outer periphery of the oriental flat wafer is used, so that the mask can cover the entire outer periphery of the wafer by about 0.5 mm to about 2.5 mm from the edge in an embodiment. Additionally, the same modification can be made to an area in which the protrusions are disposed in the shower plate; that is, the shower plate having a shape running along the inner edge of the bevel mask may be used. Letting a distance from the center to an outer periphery of the wafer be Rw, in an embodiment, the area in which the protrusions of the shower plate are disposed is an inner area from the center to Rw+T. Here, T is preferably a value in a range of −d/2<T<3d/2 (in an embodiment, 0<T<d).

In an embodiment, if a notched wafer is used, marking of 1-1.25 mm in length toward the center from a wafer edge is normally present. In this case, by making an inner dimension of the bevel mask covering a notch longer by up to 1.3-2.0 mm locally so as to completely cover the notch, deposition of a film in the vicinity of the notch can be prevented.

FIG. 8 is a partial cross-sectional view of an embodiment which is oversimplified for illustrative purposes. In this embodiment, a top plate 70′ on which a wafer 30 is placed comprises an inner portion 73 and a peripheral portion 80 (ring structure), the inner portion 73 is composed of a conductive material and the peripheral portion 80 is composed of a dielectric material. The embodiment described in U.S. Patent Publication No. 2003-0192478 (owned by ASM Japan K.K., one of the assignees of this application) can also be usable, the disclosure of which is incorporated herein by reference in its entirety. The peripheral portion 81 is a ring-shaped structure and an internal diameter of the ring-shaped structure is 80% or more, 120% or less of a diameter of the wafer.

Additionally, in an embodiment, regarding the vicinity of an inner edge of the mask 60 in which plasma concentration occurs, the top plate 70′ in which a ring-shaped recess or a trench 82 having an internal diameter of 80% or more, less than 100% of a diameter of the wafer is formed, can be used. By disposing the trench, a space of approximately 0.2-1.5 mm (preferably 0.5-1.0 mm) is created below the wafer 30. If the ring structure 80 is disposed at the periphery of the top plate 70′, an annular peripheral recess 72 of 0.5-10 mm (preferably 2-6 mm) in depth may be created in which a dielectric material such as ceramic constituting the ring structure 80 is fitted. Further, in this embodiment, the wafer is in contact with a top peripheral surface 81 of the ring structure 80 but is not contact with the trench 82 or a top surface of the inner portion 73 of the top plate 70′ so as to alleviate plasma concentration in the vicinity an inner edge of the mask, thereby actualizing film thickness uniformity. Preferably, the mask 60 rests on the ring structure 80 and the trench 82 is located slightly inside the inner edge 64 of the mask so as to alleviate plasma concentration in the vicinity of the wafer edge.

In an embodiment, no ring structure is used, but a trench can be form in the top plate itself, so as to adjust the effective distance between the upper and lower electrodes.

In an embodiment, the ring structure 80 may be made of a dielectric material such as ceramics. The material or characteristics usable for the mask can also be used for the ring structure The dielectric ring structure is effectively placed in the vicinity of an inner edge of the mask and its outer periphery, on which a plasma is concentrated. The inner portion 73 of the top plate 70′ (or the top plate 70) may be made of aluminum with an anodized surface or a surface-treated aluminum or aluminum alloy, for example.

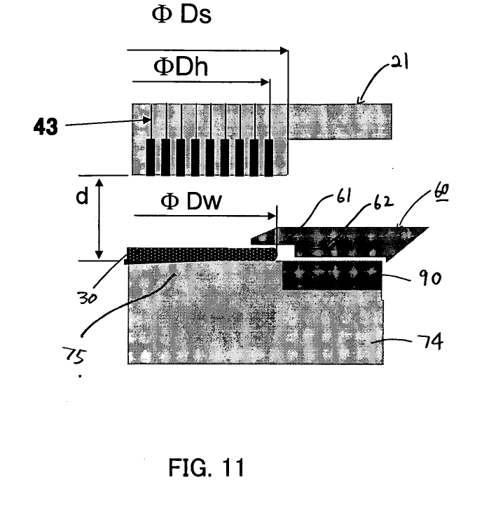

In place of the ring structure 80 with the trench 82, a ring structure 90 with no trench can be used as shown in FIG. 11 (a heater is not shown). In this figure, the ring structure 90 is fitted at an outer periphery of a top plate 74 and leveled with an inner portion 75 of the top plate 74. The mask 60 rests on a top peripheral surface of the ring structure 90. The ring structure 90 can be constituted by the same material as the ring structure 80, and the configurations of the ring structure 90 may be the same as or different from those of the ring structure 80 except that no trench is formed. For example, the thickness of the ring structure 90 may be in the range of about 1 cm to about 5 cm (preferably about 1.5 cm to about 3 cm), which may be thinner (e.g., ⅓-⅔) than that of the ring structure 80 because no trench is formed. The inner diameter may be larger than the wafer.

In an embodiment, the ring structure 90 may not be leveled with the inner portion 75 and may have a top peripheral surface higher than that of the inner portion 75 (C1 in FIG. 13). In C1 in FIG. 13, the wafer 30 is surrounded by the ring structure 90″ and the top plate 74 is made of a ceramic such as AlN.

In an embodiment, the inner diameter of the ring is smaller than the wafer, and the wafer is in contact with the ring structure 90 without touching the inner portion 75. In another embodiment, the top peripheral surface of the ring structure 90 may be lower than that of the inner portion 75. By using the ring structure 90 in combination with the mask 60 and the shower plate 21, the effective electrode distance can be reduced at or near the periphery of the wafer 30.

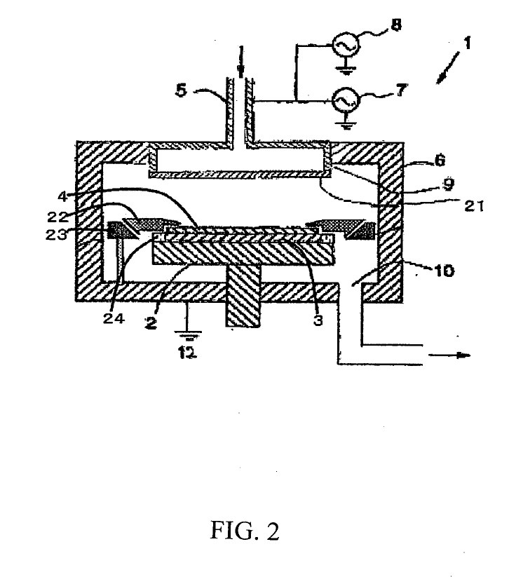

In an embodiment, a lower electrode may be constituted by a top plate 3 and a heater 2 which are integrated shown in FIG. 2, instead of being divided in parts. A substantial material of the integrated lower electrode may be aluminum or aluminum alloy which can be oxidized or surface-treated and whose service temperature may be about 150° C. to about 450° C. in an embodiment. The integrated lower electrode may also be made of aluminum nitride, which can be surface-treated and whose service temperature may be about 150° C. to about 650° C. in an embodiment. Alternatively, the heater can be embedded in the top plate.

Further, in an embodiment, plasma concentration can be alleviated by passing a gas from an edge surface of the mask's inner side toward a wafer surface through gaps or holes formed in the lower electrode, thereby controlling abnormal growth of a film thickness on a Si wafer. Additionally, if the mask is suspended and does not rest on a top peripheral surface of the top plate, a gap between the mask and the top plate can be used as gas passage for the above purposes. In an embodiment, the mask rests on the top peripheral surface of the top plate, and the top peripheral surface is provided with through-holes at or near an outer periphery of the wafer so that a gas can pass through the through-holes and the clearance between the mask and the wafer.

As for a gas being passed through, a gas which is the same as the source gas used for film formation may effectively be used. In another embodiment, a gas being passed through may be selected from a hydrocarbon CxHy (x and y are an integer of 1 or more; preferably x is 5 or more) and inert gas (N₂, Ar, He, etc.). The flow rate of such a gas may be 10 sccm to 3,000 sccm, preferably about 20 sccm to 1,000 sccm.

FIG. 2 is a schematic view showing an embodiment of the apparatus. The drawing is oversimplified for illustrative purposes. A plasma CVD film formation apparatus 1 comprises a reaction chamber 6, a gas inlet port 5, an upper electrode 9, and a lower electrode comprised of a top plate 3 and a heater 2. From a gas line (not shown), a gas is introduced through the gas inlet port 5. The circular upper electrode 9 is disposed directly below the gas inlet port 5. The upper electrode 9 has a hollow structure and a number of fine pores provided at its bottom from which a gas is jetted out toward the wafer 4. Additionally, the upper electrode 9 has a structure in which a shower plate 21 having plural gas inlet holes is replaceable so as to facilitate maintenance work and reduce component costs.

Additionally, at the bottom of the reaction chamber 6, an exhaust port 10 is provided. This exhaust port is connected to an external vacuum pump (not shown); consequently, the interior of the reaction chamber 6 is exhausted. The top plate 3 is disposed parallel to and facing the upper electrode 9. The top plate holds a wafer 4 thereon, heats the wafer 4 continuously by the heater 2, and maintains the wafer 4 at a given temperature (e.g., −50-650° C.). A peripheral portion 24 (a ring structure) of the top plate 3 is alumina in an embodiment. Further, in the vicinity of the wafer 4, a mask 22 is provided. When the top plate 3 is moved downward by a vertical movement mechanism (not shown), the mask 22 is placed on a mask-supporting stand 23; when the top plate 3 is moved upward, the mask 22 is placed on the peripheral portion 24 of the top plate 3. The gas inlet port 5 and the upper electrode 9 are electrically insulated from the reaction chamber 6 and connected to an external first radio-frequency power source 7. A second radio-frequency power source 8 may also be connected. Numeral 12 indicates grounding. Thus, the upper electrode 9 and the lower electrode function as radio-frequency electrodes and generate a plasma reaction field in the vicinity of the wafer 4. The type and characteristics of a resulting film formed on a surface of the wafer 4 vary depending on the type and the flow rate of source gas, a temperature, the RF frequency, plasma space distribution, and electric potential distribution.

In an embodiment of the present invention, plural protruding portions are disposed in the shower plate 21. The protruding portions are disposed uniformly around fine pores for introducing a gas and have a shape of a polyangular column or a polyangular pyramid such as a hexagonal column and a quadangular pyramid. Additionally, a shape of the protruding portion is not limited to a hexagonal column and a quadangular pyramid, but any shape may be used. For example, a cylindrical shape or a hemispheric shape may be used. Alternatively, not using a minute protrusion, a bank-shape having a given width may be used. If a bank shape is used, it can be a parallel lines shape that plural straight lines are disposed parallel, a lattice that plural straight lines cross each other, or a circular shape, etc. Also in these cases, protrusions having a bank shape are disposed around pores for introducing a gas. Considering that the protruding portions are formed by machine work, a protrusion having a hexagonal column or a quadangular pyramid shape is preferable.

### EXAMPLES

Examples of the present invention are described below. However, these examples are not intended to limit the present invention. The hardware conditions and process conditions are as follows:

Hardware Conditions (Wafer Size: φ200 mm):

Mask material: Alumina, silicon

Top plate: Aluminum with anodized surface

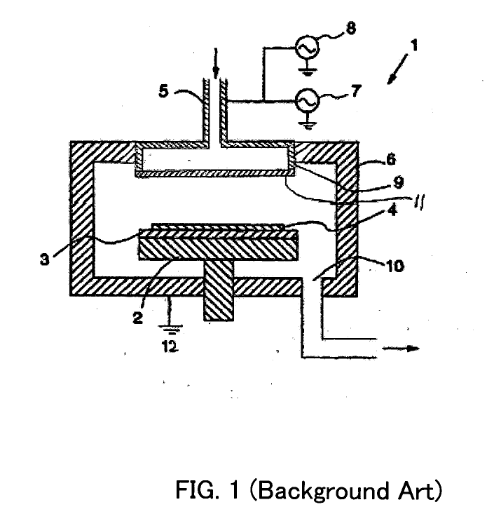

Top plate outer periphery (alumina): Flat (Inner diameter: larger than wafer, −φ203 mm; thickness—2 mm; FIG. 1), Trench (Inner diameter: smaller than wafer, −φ180 mm; thickness—4 mm; trench length—6 mm, depth—1 mm; FIG. 8)

Clearance between mask and wafer top surface: 0.075 mm, 0.325 mm, 0.575 mm, 0.775 mm

Clearance between mask and wafer side surface: 1 mm

Shower plate: Aluminum with anodized surface

Shower plate size: φ250 mm

Shower plate type: Hexagonal column protrusion

Protrusion area: φ200, φ220, φ250 mm (Gas inlet hole area: φ200, φ220, φ205 mm)

Shower plate temperature: 180° C.

Top plate temperature: 430° C.

Electrode distance: 16 mm

Covered range: 1.5 mm

Mask material: Alumina, silicon

Process Conditions:

1,3,5-trimethylbenzee (TMB): 130 sccm

He: 200 sccm

RF power: 13.56 MHz; 550 W, 430 kHz; 150 W

Pressure: 800 Pa

Targeted film thickness: 200 nm

### Example 1

### Mask Material: Alumina, Silicon

Protrusion area: φ250 mm (Gas inlet hole area: φ205 mm)

Top plate outer periphery (alumina): Flat

Clearance between mask and top wafer surface: 0.075 mm

Film thickness profiles are shown in FIG. 3. It is seen that in the case of an alumina mask as compared with a Si mask, a film thickness is rapidly increased in the vicinity of the outermost periphery by approximately 15% as compared with the center.

### Example 2

### Top Plate Outer Periphery (Alumina): Flat, Trench

Mask material: Alumina

Protrusion area: φ250 mm (Gas inlet hole area: φ205 mm)

Clearance between mask and top wafer surface: 0.075 mm

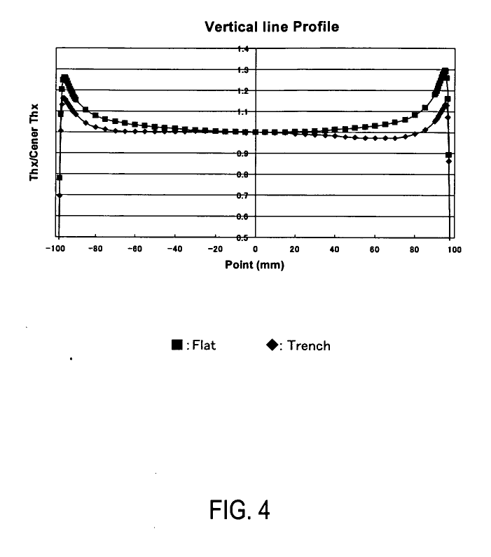

Film thickness profiles are shown in FIG. 4. As compared with a flat type, in the case of a trench type, thickening of a film in an outer periphery is decreased from 25% to 15%. This appears to be a result of widening an effective electrode distance in a wafer outer periphery by placing a wafer on a dielectric material and a gap.

### Example 3

### Clearance Between Mask and Top Wafer Surface: 0.075 mm, 0325 mm, 0575 mm, 0.775 mm

Protrusion area: φ250 mm (Gas inlet hole area: φ205 mm)

Mask material: Alumina

Top plate outer periphery (alumina): Trench

Film thickness profiles are shown in FIG. 5. Up to a clearance of 0.075-0.575 mm, film formation on a top surface peripheral portion and a side surface portion of a wafer was not observed. However, with a clearance of 0.775 mm, abnormal discharge occurred occasionally; it was judged that film formation was not acceptable. From this result, it can be seen that film formation was satisfactory when a clearance between the mask and the top wafer surface was approximately 0.05-0.7 mm.

### Example 4

### Protrusion Area: φ200, φ220, φ250 mm

Mask material: Alumina

Top plate outer periphery (alumina): Trench

Clearance between mask and top wafer surface: 0.075 mm

Film thickness profiles are shown in FIG. 6. In the case of φ250 mm (Ds=Dw+3.125d), a difference in film thickness between the center and the periphery was +12%; in the case of φ220 mm (Ds=Dw+1.25d), a difference in film thickness between the center and the periphery was −5%; in the case of φ200 mm (Ds=Dw), a difference in film thickness between the center and the periphery was −17%. Thus, by controlling a protrusion area of the shower plate, film thickness distribution was able to be controlled; and a film thickness was satisfactory in the vicinity of φ220 mm.

### Example 5

Additionally, under the same conditions as in Example 4 except that diameter Ds of the protrusion area was set at Dw, Dw+d, Dw+2d, and Dw+3d, film thickness distributions were measured. The results are shown in FIG. 10. The ratios of edge thickness to center thickness are proportionate to Ds, and when Ds was Dw+2d, almost no difference in film thickness between the center and the periphery was measured. In order to prevent the edge portion from developing a thicker film, Ds may preferably be between Dw and Dw+2d. However, even when Ds was Dw+3d, the difference in thickness was as low as about 10%.

### Example 6

### Protrusion Area: φ200, φ220, φ250 mm

Mask material: Alumina

Top plate outer periphery (alumina): Flat

Clearance between mask and top wafer surface: 0.075 mm

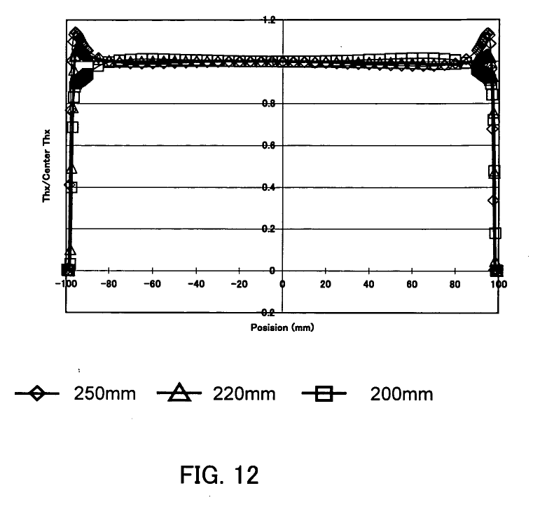

Film thickness profiles are shown in FIG. 12. In the case of φ250 mm (Ds=Dw+3.125d), a difference in film thickness between the center and the periphery was +15%; in the case of φ220 mm (Ds=Dw+1.25d), a difference in film thickness between the center and the periphery was 5%; in the case of φ200 mm (Ds=Dw), a difference in film thickness between the center and the periphery was −15%. Thus, by controlling a protrusion area of the shower plate, film thickness distribution was able to be controlled; and a film thickness was satisfactory in the vicinity of φ220 mm.

Although the present invention has been described in terms of certain preferred embodiments, other embodiments apparent to those of ordinary skill in the art are within the scope of this invention. Accordingly, the scope of the invention is intended to be defined only by the claims described. The present invention includes various embodiments and is not limited to the above preferred embodiments.

The present invention includes the following embodiments:

1) A plasma CVD film formation apparatus for forming a thin film on a wafer, which comprises a vacuum chamber, a shower plate (which serves as an upper electrode) installed inside the vacuum chamber, a top plate (which serves as a lower electrode) for placing the wafer thereon installed practically parallel to and facing the shower plate, a vertical movement mechanism moving the top plate and a wafer placed thereon vertically, and a mask preventing film formation on a top surface peripheral portion and a side surface portion of the wafer by covering the top surface peripheral portion and the side surface portion of the wafer when the top plate and the wafer placed thereon are moved upward; and which is characterized in that a clearance between the mask and the top surface of the wafer is 0.05-0.7 mm and a clearance between the mask and a side surface of the wafer is 0.05-2 mm.

2) The apparatus according to Item 1, which is characterized in that on a surface of the shower plate, plural gas inlet holes and protrusions protruding from the surface are formed, and yet which is characterized in that letting an interval between upper and lower electrodes be ‘d’ and a diameter of the wafer be ‘Dw’, a shower plate in which a diameter ‘Ds’ of an area having a plasma enhance spike of 1 mm or more, 10 mm or less is in a range of Dw−d<Ds<Dw+3d is used; and that the shower plate in which a diameter ‘Dh’ of an area having plural gas pores of Φ0.2-2 mm is in a range of Ds−2d<Dh is used.

3) The apparatus according to any of Items 1, which is characterized in that letting an interval in the vicinity of the electrode be ‘d’, a diameter of the wafer be ‘Dw’ and Ds be Dw−d<Ds<Dw+3d, the shower plate has an area of diameter ‘Ds’ which is planate with its outer periphery having a shape configured to widen an interval with the lower electrode by 2-10 mm, and a diameter ‘Dh’ of an area having plural gas pores of Φ0.2-2 mm is in a range of Ds−2d<Dh.

4) The apparatus according to any of Items 2-3, which is characterized in that an outer peripheral portion outside a plane having protrusions or a raised plane of diameter ‘Ds’ is covered by a dielectric material.

5) The apparatus according to any of Items 1-4, which is characterized in that the mask has a thickness of 2 mm or less at its innermost periphery, and at least more than one tapered portion is formed between the innermost periphery and the outermost periphery.

6) The apparatus according to any of Items 1-5, which is characterized in that the mask covers a top surface of the wafer in a range of 0.3-3 mm from the outermost periphery of the wafer.

7) The apparatus according to any of Items 1-6, which is characterized in that the mask is composed of one or more materials selected from aluminum, aluminum oxide, aluminum nitride, silicon, silicon oxide, silicon carbide, silicon nitride, boron nitride, and metal impregnated ceramic.

8) The apparatus according to any of Items 1-7, which is characterized in that the lower electrode is substantially made of AlN and its service temperature is 150° C.-650° C.

9) The apparatus according to any of Items 1-7, which is characterized in that said lower electrode is substantially made of Al and its service temperature is 150° C.-450° C.

10) The apparatus according to any of Items 2-9, which is characterized by the raised area or the area having protrusions, wherein if letting a distance from the center to an outer periphery of a wafer be Rw, ‘To’ is −d/2 to 3d/2 in a distance Rw+To from the center of the raised area to its outer periphery, and Th of a distance Rw+Th from the center of the area having plural gas inlet holes to its outer periphery is −d or greater.

11) The apparatus according to any of Items 1-10, which is characterized in that the top plate for placing the wafer thereon comprises an inner portion and a peripheral portion, and the inner portion is composed of a conductive material and the peripheral portion is composed of a dielectric material.

12) The apparatus according to any of Items 1-11, which is characterized in that a trench is formed in a part of a portion of the lower electrode on which the wafer is placed.

13) The apparatus according to any of Items 1-11, which is characterized in that a trench is formed in a portion of a ring-shaped structure placed a periphery of the top plate, on which portion the wafer is placed.

14) The apparatus according to any of Items 1-11, which is characterized in that the peripheral portion is a ring-shaped structure and an internal diameter of the ring-shaped structure is 80% or more, 120% or less of a diameter of the wafer.

15) The apparatus according to Item 14, which is characterized in that an internal diameter of the ring-shaped structure is 80% or more, less than 100%; further a trench is formed in a part of a portion of the ring-shaped structure on which the wafer is placed.

16) The apparatus according to any of Items 1-15, which is characterized in that a gas is flowed passing through inside a lower electrode from an inner edge surface of the mask toward a wafer surface.

17) The apparatus according to any of Items 1-16, which is characterized in that bulk resistivity of the mask is 10⁶ Ω·cm or higher.

18) The apparatus according to any of Items 1-16, which is characterized in that bulk resistivity of said mask is 10⁻⁵-10⁶ Ω·cm or higher.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A plasma CVD apparatus for forming a thin film on a wafer having diameter Dw and thickness Tw, comprising:
a vacuum chamber;
a shower plate installed inside the vacuum chamber which serves as one of two electrodes;
a top plate for placing the wafer thereon installed substantially parallel to and facing the shower plate, said top plate serving as the other electrode and being movable between a lower position and an upper position;
a top mask portion for covering a top surface peripheral portion of the wafer, said top mask portion being disposed at a clearance of Tw+β between a bottom surface of the top mask portion and a wafer-supporting surface of the top plate, wherein β is more than zero; and
a side mask portion disposed under the top mask portion for covering a side surface portion of the wafer when the top plate is at the upper position, said side mask portion having an inner diameter of Dw+α, wherein α is more than zero.

2. The apparatus according to claim 1, wherein α is 0.05-2 mm, and β is 0.05-0.75 mm.

3. The apparatus according to claim 1, wherein the shower plate is comprised of a gas discharge portion and a base portion, said gas discharge portion having diameter Ds which satisfies Dw−d<Ds<Dw+3d, wherein d is a distance between the shower plate and the top plate.

4. The apparatus according to claim 3, wherein Ds satisfies Dw<Ds<Dw+2d.

5. The apparatus according to claim 3, wherein the gas discharge portion is constructed by plural gas inlet bores and plasma enhance spikes protruding downward from a surface on which the plural gas inlet bores are formed, wherein Ds is an outer diameter of an area defined by outermost spikes of the plasma enhance spikes.

6. The apparatus according to claim 3, wherein the top mask portion has a bulk resistivity of about 10⁶ Ω·cm or higher.

7. The apparatus according to claim 5, wherein an area defined by outermost bores of the plural gas inlet bores has diameter Dh which satisfies Ds−2d<Dh.

8. The apparatus according to claim 5, wherein the bores have a diameter of about 0.2 mm to about 2 mm, and the spikes have a length of about 1 mm to about 10 mm.

9. The apparatus according to claim 1, wherein the top mask portion has a bulk resistivity of about 10⁻⁵ Ω·cm to about 10³ Ω·cm.

10. The apparatus according to claim 1, wherein the top mask portion and the side mask portion are integrated and constitute a bevel mask.

11. The apparatus according to claim 1, wherein the top plate is conductive and has an outer annular recess around its periphery and a dielectric ring structure placed on the annular recess for supporting the wafer thereon.

12. The apparatus according to claim 11, wherein the side mask portion is entirely or partially constituted by the ring structure.

13. The apparatus according to claim 11, wherein the dielectric ring structure has an inner annular recess.

14. The apparatus according to claim 13, wherein a plane formed by a top peripheral surface of the dielectric ring structure is higher than a plane formed by a top surface of the conductive top plate.

15. The apparatus according to claim 13, wherein the dielectric ring structure has an inner diameter of 0.8Dw to 1.2Dw.

16. The apparatus according to claim 1, wherein the top mask portion has a thickness of about 2 mm or less at an inner periphery and has an inwardly tapered portion.

17. The apparatus according to claim 1, wherein the top mask portion covers a top surface of the wafer in a range of about 0.3 mm to about 3 mm from the outermost periphery of the wafer.

18. The apparatus according to claim 1, wherein the top mask portion is composed of one or more materials selected from the group consisting of aluminum, aluminum oxide, aluminum nitride, silicon, silicon oxide, silicon carbide, silicon nitride, boron nitride, and metal impregnated ceramic.

19. The apparatus according to claim 1, wherein the top plate has outer diameter Dss which satisfies 1.04Dw<Dss<1.5Dw.

20. The apparatus according to claim 1, wherein the side mask portion is in contact with a top peripheral surface of the top plate when at the upper position.

21. The apparatus according to claim 11, wherein the side mask portion is in contact with a top peripheral surface of the dielectric ring structure.

22. A method for forming by plasma CVD a thin film on a wafer, comprising:
placing the wafer on a top plate installed substantially parallel to and facing a shower plate;
placing a top mask portion over the wafer, wherein the top mask portion covers a top surface peripheral portion of the wafer at a clearance (β) therebetween of more than zero, wherein a side mask portion is disposed at a periphery of the top plate and covers a side surface portion of the wafer at a clearance therebetween (α) of more than zero; and
applying radio-frequency power between the top plate and the shower plate to form a thin film on the wafer by plasma CVD.

23. The method according to claim 22, wherein clearance β is 0.05-0.75 mm, and clearance α is 0.05-2 mm.

24. The method according to claim 22, further comprising providing the shower plate comprised of a gas discharge portion and a base portion, said gas discharge portion having diameter Ds which satisfies Dw−d<Ds<Dw+3d, wherein Dw is a diameter of the wafer and d is a distance between the shower plate and the top plate.

25. The method according to claim 23, wherein Ds satisfies Dw<Ds<Dw+2d.

26. The method according to claim 23, wherein the gas discharge portion is constructed by plural gas inlet bores and plasma enhance spikes protruding downward from a surface on which the plural gas inlet bores are formed, wherein Ds is an outer diameter of an area defined by outermost spikes of the plasma enhance spikes.

27. The method according to claim 23, wherein the bevel mask has a bulk resistivity of about 10⁶ Ω·cm or higher.

28. The method according to claim 25, wherein an area defined by outermost bores of the plural gas inlet bores has diameter Dh which satisfies Ds−2d<Dh.

29. The method according to claim 25, wherein the bores have a diameter of about 0.2 mm to about 2 mm, and the spikes have a length of about 1 mm to about 10 mm.

30. The method according to claim 22, further comprising providing the top mask portion having a bulk resistivity of about 10⁻⁵ Ω·cm to about 10³ Ω·cm.

31. The method according to claim 22, further comprising providing the top plate being conductive and having an outer annular recess around its periphery and a dielectric ring structure placed on the annular recess for supporting the wafer thereon.

32. The method according to claim 30, wherein the dielectric ring structure has an inner annular recess.

33. The method according to claim 31, wherein the wafer is in contact exclusively with a top peripheral surface of the dielectric ring structure.

34. The apparatus according to claim 31, wherein the dielectric ring structure has an inner diameter of 0.8Dw to 1.2Dw.

35. The method according to claim 22, further comprising providing the top mask portion having a thickness of about 2 mm or less at an inner periphery and having an inwardly tapered portion.

36. The method according to claim 22, further comprising providing the top mask portion integrated with the side mask portion, which constitute a bevel mask.

37. The method according to claim 22, wherein a top surface of the wafer is covered by the top mask portion in a range of about 0.3 mm to about 3 mm from the outermost periphery of the wafer.

38. The method according to claim 22, further comprising providing the top mask portion composed of one or more materials selected from the group consisting of aluminum, aluminum oxide, aluminum nitride, silicon, silicon oxide, silicon carbide, silicon nitride, boron nitride, and metal impregnated ceramic.

39. The method according to claim 22, further comprising providing the top plate having outer diameter Dss which satisfies 1.04Dw<Dss<1.5Dw, wherein Dw is a diameter of the wafer.

40. The method according to claim 22, wherein the side mask portion is in contact with a top peripheral surface of the top plate.

41. The method according to claim 30, wherein the side mask portion is in contact with a top peripheral surface of the dielectric ring structure.

42. The method according to claim 22, wherein the film formed on the wafer has a non-uniformity of film thickness of about 10% or less.
